(19) United States
(12) Patent Application Publication
(10) Pub. No.: US 2023/0288875 A1
(43) Pub. Date: Sep. 14, 2023

(54) BLACK COMPONENT DECORATED WITH STONES AND METHOD FOR MANUFACTURING SAME

(71) Applicant: Omega SA, Biel/Bienne (CH)

(72) Inventors: Frédéric JEANRENAUD, La Chaux-de-Fonds (CH); Gregory KISSLING, La Neuveville (CH); Stéphane LAUPER, Cortaillod (CH); Agnès MARLOT DOERR, Neuchatel (CH); Csilla MIKO, Essertines-sur-Yverdon (CH)

(73) Assignee: Omega SA, Biel/Bienne (CH)

(21) Appl. No.: 18/040,369

(22) PCT Filed: Jul. 23, 2021
(86) PCT No.: PCT/EP2021/070692

§ 371 Date: Feb. 2, 2023

(30) Foreign Application Priority Data
Aug. 11, 2020 (EP) 20190566.8

(51) Int. Cl. G04B 19/12; G04B 45/00; G04D 3/00; A44C 17/02

(52) U.S. Cl. CPC G04B 19/12; G04B 45/0015; G04B 45/0007; G04D 3/0069; A44C 17/02

(57) ABSTRACT

A component and method of making the internal parts or movement for a timepiece or piece of jewelry that includes a substrate partially coated with a black layer and decorated with at least one stone, said black layer including carbon nanotubes or aluminum oxide, said substrate being at least devoid of the black layer on the portion facing the stone.

### FIELD OF THE INVENTION

The invention relates to a component intended for the internal parts or movement of a timepiece or piece of jewellery. It further relates to the method for manufacturing said component.

### BACKGROUND OF THE INVENTION

The black “colour” can be obtained in the mass of a material by its intrinsic colour or by the addition of pigments or dyes within the material. The black “colour” can also be present on the surface only. This surface colouring can be achieved in a number of ways, typically by oxidation/sulphurisation/carburisation of a metal substrate or by deposition of an oxide/sulphide/carbide on a substrate. Carbon is thus a well-known element used to blacken a surface. Deposited in an elongated manner in the form of nanotubes, the material formed can resemble a perfectly absorbent black body, with light absorption coefficients of up to 99.96% in the visible and near infrared range. This black is so perfect that it can hide 3D shapes of an object viewed from the front.

The use of black coatings is well known in the horological industry. European patent document No. 3 327 517 discloses a dial with a first substrate coated with a black layer of nanotubes facing the watch glass and with a second substrate fixed to the first substrate on the surface opposite the glass. The first substrate is perforated to provide openings acting as windows intended to form indexes. The second substrate comprises a luminescent coating at least in the areas facing the openings so as to create a contrast at the first substrate between the black layer and the illuminated indexes.

Thus, contrast is achieved by superimposing two substrates with different coatings. This superposition avoids the need to selectively deposit both coatings on the same surface and manipulate the particularly fragile nanotube layer more than necessary. This superposition nonetheless has the drawback of requiring two substrates to be manufactured, which increases production costs.

Swiss patent document No. 711 141 discloses a method for manufacturing a dial, wherein the decoration, i.e. indexes, is affixed to the carbon black coating. The decoration is manufactured separately from the dial and then simply added thereto, which greatly facilitates the manufacture of the dial. However, this manufacturing technique is unsuitable for certain types of decorations where the black colour underlying the decoration affects the aesthetics and/or brilliance of the decoration.

In particular, this manufacturing technique is not very suitable for a decoration made of stones, in particular diamonds. The difficulty lies in setting the stones on the dial coated with a black layer. The latter must be discontinuous at the location of the stones, otherwise the brilliance of the stones will be degraded, while at the same time perfectly surrounding the stones to obtain the desired contrast. Particular attention must be paid to the manufacturing method so as not to damage the carbon nanotube layer. The layer can be so friable that it is almost impossible to touch it without damaging the surface, showing shiny tints or even holes contrasting with the original colour of the carbon nanotubes.

### AIMS OF THE INVENTION

The aim of the present invention is to provide a method for manufacturing a horological or jewellery component coated in black and decorated with stones, and more particularly set with stones. This method is developed in such a way that the black coating is not damaged, while at the same time obtaining a discontinuous black layer at the location of the stones.

The manufacturing method according to the invention cannot thus simply involve adding a decoration, in this case stones, to the coating as in the prior art. According to the invention, the decoration formed by the stones is manufactured directly on the substrate with the black layer selectively removed so as to maintain a surface free of any black beneath the decoration.

More specifically, the invention relates to a method for manufacturing a component intended for the internal parts or movement of a timepiece or piece of jewellery, said component including a substrate at least partially coated with a black layer comprising carbon nanotubes or aluminium oxide, the coated substrate being decorated with at least one stone seated in a bed provided in the substrate, the latter being at least devoid of the black layer on the surface of the bed, said method comprising:
a step a) of providing the substrate,
   followed, in an unspecified order, by
a step b) of depositing the black layer on the substrate,
a step c) of machining the bed in the substrate,
a step e) of positioning and fixing the stone within the bed,
   said method comprising an additional step d) of selectively removing the black layer previously deposited on the substrate so that at least the surface of the bed is devoid of the black layer.

According to an alternative embodiment of the method which is applicable when the black layer contains carbon nanotubes, step b) is replaced by a step b′) of depositing a layer of a precursor including carbon nanotubes. The additional step d) is thus replaced by an additional step d′) of selectively removing the precursor layer so that at least the surface of the bed is devoid of the precursor layer. This method further includes a step f) which consists of chemical or laser etching the precursor layer to reveal the black carbon nanotube layer.

The selective removal step d) or d′) can be carried out mechanically, for example using a setting tool, or preferably by laser ablation. The selective removal can also be carried out indirectly during the step of machining the bed or during a step of growing a support for the stone on the substrate via, for example, an additive manufacturing operation and more specifically by inkjet additive manufacturing.

The present invention further relates to the component of the internal parts or movement for a timepiece or piece of jewellery comprising a substrate partially coated with a black layer and decorated with at least one stone seated in a bed provided in or on the substrate, said black layer comprising carbon nanotubes or aluminium oxide, said substrate being at least devoid of the black layer on the portion facing the stone or, in other words, on the surface of the bed.

For a diamond decoration on a carbon nanotube coating, the present invention proposes producing a horological or jewellery component with two allotropic forms of carbon on the surface, one being very black for the carbon nanotubes and the other being very white for the diamond, allowing for very marked contrasts in brilliance.

Other features and advantages of the present invention will appear upon reading the following description given with reference to the accompanying drawings.

### BRIEF DESCRIPTION OF THE DRAWINGS

FIG. 1 shows a plan view of a timepiece provided with a dial coated and decorated with stones according to the method of the invention. An enlargement shows a stone with the setting element.

FIGS. 2 to 7 are diagrammatic views of different embodiments of the method according to the invention producing with the successive steps implemented.

### DESCRIPTION OF THE INVENTION

The invention relates to a component intended for the internal parts or movement of a timepiece or piece of jewellery. It can be selected from the non-exhaustive list comprising a dial, a hand, an index, an applique, an oscillating weight, a plate, and a bridge, etc. According to the invention, this component is at least partially coated with a black layer. The invention further relates to an assembly of two of said components at least partially coated with the black layer.

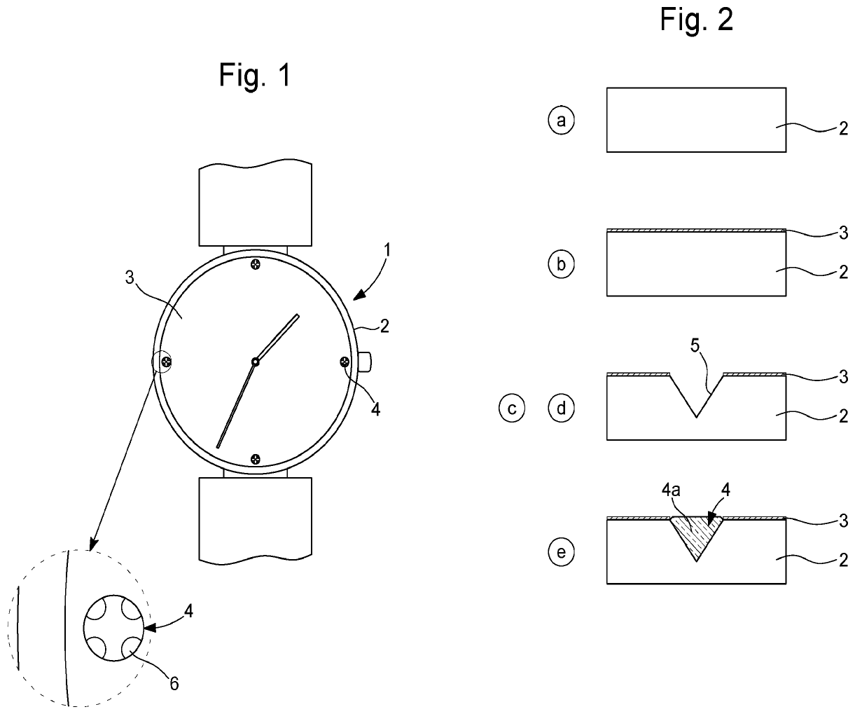

The invention will be described hereinbelow in the context of an application to a watch dial 1 formed by a substrate 2 coated with a black layer 3 as shown in FIG. 1. Said substrate can be made of a metal material such as steel, titanium, aluminium, a titanium or aluminium alloy, brass or any other copper alloy. It can also be made of a ceramic, cermet, sapphire, composite or polymer material. The substrate 2 is decorated, and preferably set, with one or more stones 4 distributed within the black layer 3. These can be precious stones such as diamond, semi-precious stones or synthetic stones such as zirconia, etc. According to the invention, the substrate is at least devoid of the black layer on the portions facing the stones. The black layer can be present so as to be flush with the table of the stone. The substrate can also conceivably be decorated with several alignments of stones, with the substrate including a black layer between the alignments.

The substrate 2 includes a bed 5, shown in FIG. 2, which acts as a seat for the stone 4 and more particularly for the pavilion 4a of the stone. The stone is preferably fixed within the seat by setting, using a setting element 6 shown in the enlargement of FIG. 1. This can be claws of a setting disposed in the bed, grains which form an integral part of the substrate, or undercuts in a bed for a baguette or invisible setting, etc. According to the invention, the setting element is preferably also coated with the black layer so as to achieve a setting that appears invisible to the user. Visually, it blends into the black background of the dial. Alternatively, the present invention does not preclude the stone from being bonded within the seat with an adhesive that does not degrade the brilliance of the stone.

According to an alternative embodiment of the invention, the black layer contains carbon nanotubes. The carbon nanotube layer contains at least 1 wt %, preferably at least 10 wt %, of carbon nanotubes. Said layer can be a varnish comprising at least 1 wt %, preferably at least 10 wt %, of carbon nanotubes. The higher the proportion, the darker the shade. The carbon nanotubes are randomly dispersed within this varnish. This varnish can be deposited, for example, by spraying. Alternatively, the layer contains at least 50 wt %, at least 60 wt %, at least 70 wt %, at least 80 wt %, or at least 90 wt % of carbon nanotubes aligned vertically relative to the plane of the substrate, the remainder consisting of other forms of carbon. Preferably, the layer contains 100 wt % of carbon nanotubes aligned vertically relative to the plane of the substrate. The vertical alignment of the nanotubes results in a deeper black than the random orientation of the carbon nanotubes in the varnish, but has the drawback of having a lower mechanical strength than the varnish. In order to overcome this drawback, a protective layer can be deposited on the black layer, however this results in a reduction of the light absorption coefficient. This protective layer can be a varnish or a thin layer of a material, for example Al₂O₃, TiO₂ or SiO₂, or a stack of layers of one or more of these materials deposited by ALD (Atomic Layer Deposition). The vertically-oriented nanotubes are deposited by vacuum methods such as PVD (Physical Vapour Deposition), CVD (Chemical Vapour Deposition) or laser ablation synthesis. The carbon nanotube layer has a thickness of between 1 and 100 μm.

According to another alternative embodiment, the black layer is a layer comprising mainly aluminium oxides AlₓO_{y} such as Al₂O₃ with additional non-ferrous metal oxides such as, for example, copper, zinc or manganese oxides. This layer contains at least 90% AlₓO_{y}, preferably 100% AlₓO_{y}. The aluminium oxide has an aluminium content of between 45 wt % and 65 wt %, preferably between 45 wt % and 50 wt %. This layer has a thickness between 1 and 50 microns, preferably between 2 and 10 microns, and more preferably between 4 and 7 microns. It can be deposited by PVD, CVD or PECVD (Plasma-Enhanced Chemical Vapour Deposition).

The component according to the invention can be manufactured according to several embodiments of the method which are diagrammatically illustrated in FIGS. 2 to 7. For the sake of simplicity, FIGS. 2 to 7 show only the substrate provided with a bed for the seat of the stone and do not show the setting element. Any step involving the machining of the bed includes, where appropriate, the mechanical preparation of the setting element such as the grains.

The method for manufacturing the component includes, in an unspecified order for steps b) to e):
a step a) of providing the substrate 2,
a step b) of depositing the black layer 3 on the substrate 2 or b′) of depositing a layer of a precursor 7 comprising carbon nanotubes for the alternative embodiment with carbon nanotubes,
a step c) of machining the bed 5 in or on the substrate 2,
a step d) of selectively removing the black layer 3 or d′) of selectively removing the precursor layer 7 previously deposited on the substrate 2, such that at least the surface of the bed 5 is devoid of the black layer 3 or of the precursor layer 7,
a step e) of positioning and fixing, and preferably setting, the stone 4 within the bed 5.

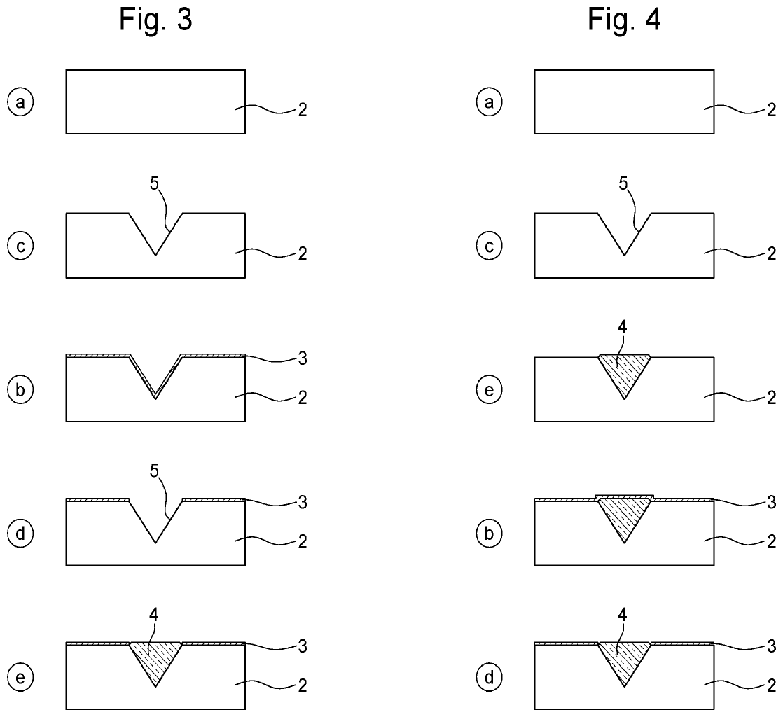

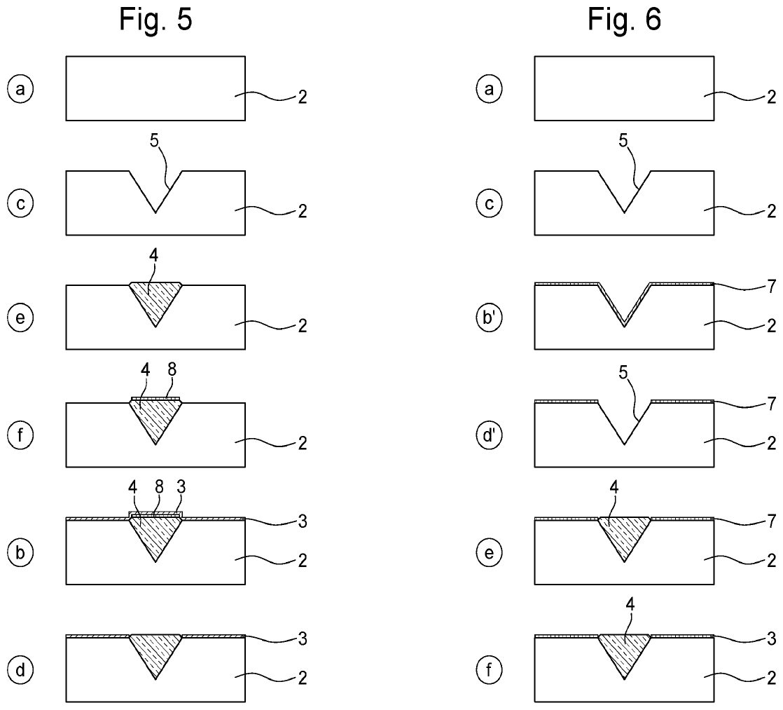

According to a first embodiment illustrated in FIGS. 2 to 5, the method for manufacturing the component comprises:
A step a) of providing the substrate 2 (FIG. 2-5),
A step b) of depositing the black layer 3 on all or part of the substrate 2, including the area intended to form the bed (FIG. 2), the bed 5 (FIG. 3), or the upper surface of the stone 4, i.e. the table and the crown for a cut stone (FIG. 4-5),
A step d) of selectively removing the black layer 3 from the area intended to form the bed 5 (FIG. 2), the bed 5 (FIG. 3) or the upper surface of the stone 4 (FIG. 4-5).

It further comprises a step c) of machining the bed 5 in the substrate 2 and a step e) of positioning and fixing the stone 4 on the substrate 2. Fixing includes setting as well as other fixing techniques such as bonding.

For the alternative embodiment shown in FIG. 2, the black layer 3 is deposited on the substrate 2 prior to machining the bed 5. The black layer 3 is then removed during the machining of the bed 5, i.e. steps c) and d) are one and the same. Finally, step e) is carried out.

For the alternative embodiment shown in FIG. 3, the black layer 3 is deposited on the substrate 2 after step c) of machining the bed 5. The black layer 3 is then removed from the bed 5. Removal can be carried out mechanically and more specifically manually using a setting tool. According to a preferred embodiment, this selective removal is carried out by laser ablation and more preferably with a pulsed laser such as a nanosecond, picosecond or femtosecond laser. Finally, step e) is carried out.

For the alternative embodiment shown in FIG. 4, the black layer 3 is deposited on the substrate 2 which has already been decorated with the stone 4. The black layer 3 on the stone 4 is then removed mechanically or preferably by laser ablation with a pulse laser as in the prior case. This alternative embodiment in FIG. 4 is preferred because, after the black layer has been selectively removed, there is no longer any need to handle the surface, unlike in the alternative embodiment in FIG. 3, where the substrate must still be set after the selective removal step.

For the alternative embodiment shown in FIG. 5, the substrate 2 is decorated with the stone 4 according to step e). The method then includes an additional step f) of applying a mask 8 to the stone 4. The mask can be a lacquer, an adhesive, or a photosensitive film, etc. It can be deposited, for example, by photolithography, stereolithography, digital printing or manually for an adhesive or film. The black layer 3 is then deposited in step b) on the substrate 2, including on the mask 8. Finally, the black layer 3 is selectively removed with the mask 8 in step d). The mask can be removed by laser ablation or mechanically, for example manually using a dedicated tool. Alternatively (not shown), the mask could be positioned in the bed before the stone is positioned. The black layer is then deposited and selectively removed before the stone is positioned.

According to a second embodiment illustrated in FIG. 6, step b) is replaced by step b′) of depositing a layer of a precursor 7 on the substrate 2, including on the surface of the bed 5. Step b′) includes the deposition of the precursor layer and annealing to polymerise the precursor. This alternative embodiment applies for a black layer with a carbon nanotube base. The precursor contains a polymer and carbon nanotubes. The weight percentage of carbon nanotubes is between 0.1 and 15 wt % and the weight percentage of polymer is between 85 and 99.9 wt %. The polymer can be selected from thermoplastics such as polyamide, polybutene, polyethylene, polyimide, polypropylene, polystyrene, polyvinyl acetate and polymethyl methacrylate or from thermosets such as polyepoxide and polyurethane. To improve the adhesion between the polymer and the carbon nanotubes, the latter can be functionalised beforehand. For example, for a polyimide matrix, the carbon nanotubes can be functionalised beforehand by etching in an acidic medium, for example in nitric acid. The precursor comprising the mixture of carbon nanotubes distributed in the polyimide matrix is deposited and polymerised at a temperature of between 150 and 350° C. for a duration of between 1 and 7 hours.

Step d) of selectively removing the precursor layer 7 deposited in the bed 5 is then carried out. Preferably, this selective removal is carried out by laser ablation, but it could also be achieved manually using a suitable tool. This is followed by step e) of positioning and fixing the stone 4 within the bed 5 of the substrate 2. Finally, in step f), the precursor layer 7 is chemically or laser etched to reveal the carbon nanotubes in the precursor layer to form the black layer 3. Chemical etching can be carried out in an acidic medium (e.g. formic acid, acetic acid, sulphuric acid, nitric acid, hydrochloric acid or hydrofluoric acid) or in a suitable solvent (e.g. m-Cresol) depending on the nature of the polymer matrix. This etching step partially dissolves the polymer matrix of the precursor layer, creating a surface roughness and thus revealing a microstructure rich in carbon nanotubes and suitable for trapping light. Laser etching with a pulsed laser (e.g. a femtosecond or picosecond laser) can also be considered in order to create such a surface microstructure.

Alternatively (not shown), step b′) can be carried out before step c) of machining the bed, steps c) and d′) thus being a single, concomitant step of machining the bed and selectively removing the precursor layer from the bed. Alternatively (not shown), the precursor layer can be deposited on the substrate set with the stone, with the selective removal of the precursor thus being carried out on the stone.

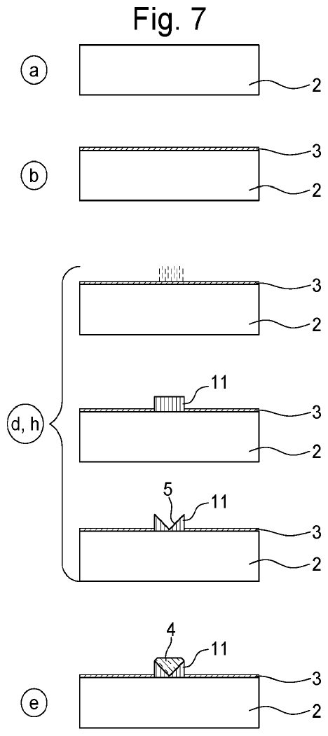

According to a third embodiment illustrated in FIG. 7, the method comprises an additional step h) of growing material on the substrate 2 coated with the black layer to form a support 11 intended to receive the stone 4. It thus successively includes:
a step a) of providing the substrate 2,
a step b) of depositing the black layer 3 on the substrate 2,
a step h) of growing material on the coated substrate 2 to form the support 11, this step being concomitant with step d) of selectively removing the black layer 3,
a step e) of positioning and fixing the stone 4 within the bed 5 provided on the substrate 2 in the support 11.

The material growth step is carried out by additive manufacturing such as digital printing, electroforming, selective laser melting or any other derived additive method. The material can be metallic, ceramic or polymeric. During this step, the black layer 3 will automatically be selectively removed from the support 11, thus freeing the substrate 2 facing the stone 4 to be set.

The bed 5 can be directly produced during the growth step h) or can be machined at a later stage before step e).

All embodiments are shown for a setting element which is covered with a black layer so as to blend in with the background of the dial. However, the present invention does not preclude the selective removal of the black layer from the bed from also including the setting element.

Finally, the present invention further relates to an assembly comprising a first component and a second component, each intended for the internal parts or movement of a timepiece or piece of jewellery. According to the invention, the first and second components include at least one portion coated with the black layer. Preferably, the first component can move relative to the second component and is mounted facing the latter. This first component is decorated with one or more stones. For example, the first component is a hand coated with the black layer and decorated with a stone set or bonded to the tip of the hand, and the second component is a dial coated with the black layer.

### Key

(1) Dial
(2) Substrate
(3) Black layer
(4) Stone
   a. Pavilion
(5) Bed
(6) Setting element
(7) Precursor layer
(8) Mask
(11) Support

1-37. (canceled)

38. A component of the internal parts or movement for a timepiece or piece of jewelry comprising a substrate partially coated with a black layer and decorated with at least one stone seated in a bed provided in the substrate or in a support positioned on the substrate, said black layer comprising carbon nanotubes or aluminum oxide, said substrate being at least devoid of the black layer on the surface of the bed.

39. The component according to claim 38, wherein the black layer lies flush with the table of the stone.

40. The component according to claim 38, wherein the stone is set within the bed using a setting element.

41. The component according to claim 40, wherein said setting element is also coated with the black layer.

42. The component according to claim 38, wherein it includes a plurality of alignments of stones, the black layer being disposed between the alignments.

43. The component according to claim 38, wherein the black layer is a varnish comprising at least 1 wt %, preferably at least 10 wt % of carbon nanotubes, said carbon nanotubes having a random orientation within the varnish.

44. The component according to claim 38, wherein the black layer contains at least 50 wt %, at least 60 wt %, at least 70 wt %, at least 80 wt %, or at least 90 wt % of carbon nanotubes aligned vertically relative to the plane of the substrate, the remainder consisting of other forms of carbon.

45. The component according to claim 38, wherein the black layer contains 100 wt % of carbon nanotubes aligned vertically relative to the plane of the substrate.

46. The component according to claim 38, wherein the black layer comprising carbon nanotubes has a thickness of between 1 and 100 μm.

47. The component according to claim 38, wherein the black layer comprises at least 90 wt % of aluminum oxide, preferably 100 wt % of aluminum oxide.

48. The component according to claim 47, wherein the aluminum oxide has an aluminum content of between 45 wt % and 65 wt %, preferably between 45 wt % and 50 wt %.

49. The component according to claim 47, wherein the black layer has a thickness between 1 and 50 microns, preferably between 2 and 10 microns, and more preferably between 4 and 7 microns.

50. The component according to claim 38, wherein it is selected from the group consisting of a dial, an index, a hand, an applique, an oscillating weight, a plate and a bridge.

51. An assembly comprising the component according to claim 38 and another component of the internal parts or movement for a timepiece or piece of jewelry, said other component being at least partially coated with said black layer.

52. The assembly according to claim 51, wherein the component is disposed facing said other component and mounted such that it can move relative to said other component.

53. The assembly according to claim 51, wherein the component is a hand and in that the other component is a dial.

54. A timepiece or piece of jewelry comprising the component according to claim 38.

55. A method for manufacturing a component intended for the internal parts or movement of a timepiece or piece of jewelry, said component including a substrate at least partially coated with a black layer and decorated with at least one stone seated in a bed provided in or on the substrate, said black layer comprising carbon nanotubes or aluminum oxide, and said substrate being at least devoid of the black layer on the surface of the bed, the method comprising:
a step a) of providing the substrate,
followed, in an unspecified order, by
a step b) of depositing the black layer on the substrate,
a step c) of machining the bed in or on the substrate,
a step e) of positioning and fixing the stone within the bed,
said method comprising an additional step d) of selectively removing the black layer previously deposited on the substrate so that at least the surface of the bed is devoid of the black layer.

56. The manufacturing method according to claim 55, wherein it successively includes:
the step a) of providing the substrate,
the step b) of depositing the black layer on the substrate,
the step d) of selectively removing the black layer from the bed produced in step c) of machining the bed in the substrate, steps c) and d) being one and the same step,
the step e) of positioning and fixing the stone within the bed of the substrate.

57. The manufacturing method according to claim 55, wherein it successively includes:
the step a) of providing the substrate,
the step c) of machining the bed in the substrate,
the step b) of depositing the black layer on the substrate,
the step d) of selectively removing the black layer from the surface of the bed,
the step e) of positioning and fixing the stone within the bed of the substrate.

58. The manufacturing method according to claim 55, wherein it successively includes:
the step a) of providing the substrate,
the step c) of machining the bed in the substrate,
the step e) of positioning and fixing the stone within the bed of the substrate,
the step b) of depositing the black layer on the substrate, including on the free surface of the stone,
the step d) of selectively removing the black layer deposited on the free surface of the stone.

59. The manufacturing method according to claim 55, wherein it successively includes:
the step a) of providing the substrate,
the step c) of machining the bed in the substrate,
the step e) of positioning and fixing the stone within the bed of the substrate,
a step f) of positioning a mask on the free surface of the stone,
the step b) of depositing the black layer on the substrate, including on the mask,
the step d) of selectively removing the black layer by removing the mask.

60. Manufacturing method according to claim 55, wherein it successively includes:
the step a) of providing the substrate,
the step c) of machining the bed in the substrate,
a step f) of positioning a mask on the surface of the bed,
the step b) of depositing the black layer on the substrate, including on the mask,
the step d) of selectively removing the black layer by removing the mask,
the step e) of positioning and fixing the stone within the bed of the substrate.

61. The manufacturing method according to claim 55, wherein it successively includes:
the step a) of providing the substrate,
the step b) of depositing the black layer on the substrate,
a step h) of growing material on the substrate to form a support, said step h) resulting in selectively removing the black layer from the support on the substrate in accordance with step d),
the step e) of positioning and fixing the stone within the bed provided on the substrate in the support.

62. The manufacturing method according to claim 61, wherein the material growth step h) is carried out by additive manufacturing, by electroforming or by selective laser melting.

63. The method for manufacturing a component intended for the internal parts or movement of a timepiece or piece of jewelry, said component including a substrate at least partially coated with a black layer and decorated with at least one stone seated in a bed provided in the substrate, said black layer comprising carbon nanotubes, and said substrate being at least devoid of the black layer on the surface of the bed, the method comprising:
a step a) of providing the substrate,
followed, in an unspecified order, by
a step b′) of depositing and annealing a precursor layer comprising carbon nanotubes on the substrate,
a step c) of machining the bed in the substrate,
a step e) of positioning and fixing the stone within the bed of the substrate,
said method comprising an additional step d′) of selectively removing the precursor layer such that at least the surface of the bed is devoid of the precursor layer and a step f) of chemical or laser etching the precursor layer to form the black layer on the substrate.

64. The manufacturing method according to claim 63, wherein it successively includes:
the step a) of providing the substrate,
the step c) of machining the bed in the substrate,
the step b′) of depositing and annealing the precursor layer comprising carbon nanotubes on the substrate, including on the surface of the bed,
the step d′) of selectively removing the precursor layer deposited on the surface of the bed,
the step e) of positioning and fixing the stone within the bed of the substrate,
the step f) of chemical or laser etching the precursor layer to form the black layer on the substrate.

65. The manufacturing method according to claim 63, wherein it successively includes:
the step a) of providing the substrate,
the step b′) of depositing and annealing a layer of a precursor on the substrate,
the step c) of machining the bed in the substrate, resulting in selectively removing the precursor layer from the bed,
the step e) of positioning and fixing the stone within the bed of the substrate,
the step f) of chemical or laser etching the precursor layer to form the black layer on the substrate.

66. The manufacturing method according to claim 63, wherein it successively includes:
the step a) of providing the substrate,
the step c) of machining the bed in the substrate,
the step e) of positioning and fixing the stone within the bed of the substrate,
the step b′) of depositing and annealing a layer of a precursor on the substrate, including on the free surface of the stone,
the step d′) of selectively removing the precursor layer deposited on the free surface of the stone,
the step f) of chemical or laser etching the precursor layer to form the black layer on the substrate.

67. The manufacturing method according to claim 63, wherein the precursor contains a polymer and carbon nanotubes.

68. The manufacturing method according to claim 67, wherein the weight percentage of carbon nanotubes is between 0.1 and 15 wt % and the weight percentage of polymer is between 85 and 99.9 wt %.

69. The manufacturing method according to claim 67, wherein the polymer is selected from the group consisting of polyamide, polybutene, polyethylene, polyimide, polypropylene, polystyrene, polyvinyl acetate, polymethyl methacrylate, polyepoxide and polyurethane.

70. The manufacturing method according to claim 63, wherein the precursor layer has a thickness between 10 and 200 microns, preferably between 100 and 200 microns.

71. The manufacturing method according to claim 55, wherein the selective removal step d) or d′) is carried out mechanically or by laser ablation.

72. The manufacturing method according to claim 55, wherein the black layer comprising carbon nanotubes is deposited by spraying, PVD or CVD.

73. The manufacturing method according to claim 55, wherein the black layer comprising aluminum oxide is deposited by PVD, CVD or PECVD.

74. The manufacturing method according to claim 55, wherein the stone is fixed by setting.

75. A timepiece or piece of jewelry comprising the component according to the assembly according to claim 51.
